(19) United States
(12) Patent Application Publication
(10) Pub. No.: US 2026/0305374 A1
(43) Pub. Date: Oct. 1, 2026

(54) METHODS FOR MAKING HIGH-DENSITY INTERCONNECTS IN ADVANCED SEMICONDUCTOR PACKAGING

(71) Applicant: Purdue Research Foundation, West Lafayette, IN (US)

(72) Inventors: Tiwei Wei, West Lafayette, IN (US); Ainur Sabirova, West Lafayette, IN (US)

(21) Appl. No.: 19/454,336

(22) Filed: Jan. 20, 2026

Related U.S. Application Data
(60) Provisional application No. 63/747,302, filed on Jan. 20, 2025.

(51) Int. Cl. H10W 70/05; C25D 5/02; C25D 7/12

(52) U.S. Cl. CPC H10W 70/095; C25D 5/022; C25D 7/12

(57) ABSTRACT

The invention generally relates to methods for making high-density interconnects in advanced semiconductor packaging. In certain aspects, the invention provides methods for making high-density interconnects on a substrate that involve coupling a first single layer membrane to a substrate, wherein the first single layer membrane has a first patterned lay-out that comprises first horizontal lines and first vertical vias; conducting an electroplating process to produce first horizontal metal lines and first vertical metal vias on the substrate; and releasing the first single layer membrane from the substrate that now comprises a first pattern of the first horizontal metal lines and the first vertical metal vias.

### RELATED APPLICATION

The present application claims the benefit of and priority to U.S. provisional patent application Ser. No. 63/747,302, filed Jan. 20, 2025, the content of which is incorporated by reference herein in its entirety.

### FIELD OF THE INVENTION

The invention generally relates to methods for making high-density interconnects in advanced semiconductor packaging.

### BACKGROUND

Redistribution layer (RDL) is an integral part of 3D IC integration, especially for 2.5D IC integration with a passive interposer. The RDL allows for circuitry fan-outs of and allows for lateral communication between the chips attached to the interposer. There are at least two ways to fabricate RDLs. The first method is by using polymers, such as polyimide (PI) PWDC 1000 (Dow Corning), benzocyclobutene (BCB) cyclotene 4024-40 (Dow Chemical), polybenzo-bisoxazole (PBO) HD-8930 (HD Micro Systems), and the fluorinated aromatic AL-X 2010 (Asahi Glass Corporation) to make the passivation layer and electroplating (such as Cu) to make the metal layers. This method has been used by the OSAT (outsourced semiconductor assembly and test) to fabricate RDLs (without using semiconductor equipment) for wafer-level (fan-in) chip scale package, embedded wafer-level (fan-out) ball grid array package, and (fan-out) redistribution chip package. The second method is the Cu damascene method, which is primarily modified from the conventional semiconductor back-end-of-line to make the Cu metal RDLs. In general, much thinner structures (both dielectric layers and Cu RDLs), finer pitches, smaller line-widths, and spacing can be obtained with the Cu damascene method, which will be the emphasis in this study. The polymer/Cu-plating method will be mentioned first. Also, the fabrication of TSV and Cu reveal will be presented.

The RDL (Redistribution Layer) build-up process on silicon or glass substrates typically involves multiple metal layers and dielectric layers between them. Traditional RDL metal fabrication, includes steps such as dielectric layer deposition, dielectric layer etching, metal layer deposition, and chemical mechanical polishing (CMP). This process is repeated layer by layer to create multi-layer RDL metal interconnects. For a six-layer RDL metal interconnect on a silicon or glass substrate, this sequence must be repeated six times to ensure robust metal connections for advanced substrate interconnects. The entire RDL fabrication process involves lithography, photoresist coating, chemical vapor deposition (CVD), physical vapor deposition (PVD), etching, and chemical mechanical polishing, which consumes significant amounts of chemicals, water, and other resources.

Researchers are exploring additive manufacturing for metal printing to build single-layer metal on the substrate. However, this method does not scale well for multi-layer metal interconnects and is generally limited to using silver, as copper is challenging to implement. Additionally, additive manufacturing for electroplating, using a technique based on Local Electrochemical Modeling (LEM), involves applying a controlled external electrical potential through a print head to a precursor solution, which initiates localized plating or electrodeposition. This method allows for fine control over parameters such as print speed, height, and linewidth by adjusting the applied voltage and distances. It accommodates a wide range of materials, from conductive metals like copper to high-viscosity polymers and semiconductors like MoO3. While Direct Ink Writing (DIW) can achieve higher speeds in some cases, it often sacrifices linewidth control. DIW can achieve high-resolution printing with linewidths below 20 micrometers and can produce lines as fine as 18 micrometers in height, a feature not available in many digital printing methods limited to thin layers. However, this approach does not scale well to large areas.

### SUMMARY

The invention generally provides a cost-effective, low-cost multi-layer RDL fabrication method using customized advanced membrane technology. This customized membrane template can be patterned according to the metal interconnect layout and adapted for multi-layer configurations. This approach can achieve metal line sizes as small as 1 micrometer, potentially reducing energy consumption and water usage. The fabrication process time can be reduced by 80% compared to traditional methods.

In certain aspects, the invention provides a method for making high-density interconnects on a substrate, the method comprising: coupling a first single layer membrane to a substrate, wherein the first single layer membrane has a first patterned lay-out that comprises first horizontal lines and first vertical vias; conducting an electroplating process to produce first horizontal metal lines and first vertical metal vias on the substrate; and releasing the first single layer membrane from the substrate that now comprises a first pattern of the first horizontal metal lines and the first vertical metal vias.

In certain embodiments, the method is conducted without photolithography or chemical polishing. In certain embodiments, the first horizontal metal lines and the first vertical metal vias have a width of at least 1 micrometer. In certain embodiments, the first horizontal metal lines and the first vertical metal vias have a diameter of at least 1 micrometer. In certain embodiments, the first single layer substrate comprises a polymer and the substrate is a metal substrate. In certain embodiments, the substrate is a copper substrate.

In certain embodiments, the method is conducted with the first single layer membrane and a second single member membrane. In certain embodiments, the second single member membrane has a second patterned lay-out that comprises second horizontal lines and second vertical vias and the second patterned lay-out is different from the first patterned lay-out. In certain embodiments, the electroplating process produces the first patterned lay-out and the second patterned layout on the substrate, thereby producing a multi-layer, multi-dimensional patterned lay-out on the substrate. In certain embodiments, the electroplating process produces the first patterned lay-out and the second patterned layout on the substrate at the same time.

In other aspects, the invention provides a method of making a single layer membrane having a patterned lay-out, the method comprising: providing a polymer membrane; attaching the polymer membrane to a tape film; coupling a patterned photomask to the polymer membrane, the patterned photomask comprising a pattern of distributed cylindrical isopores; exposing the polymer membrane and patterned photomask to light to thereby etch the pattern from the photomask onto the polymer membrane; and removing the tape film, thereby producing a single layer membrane having a patterned lay-out.

In certain embodiments, single layer membrane having the patterned lay-out is used in a process to produce a substrate having the patterned lay-out. In certain embodiments, the method is conducted without photolithography or chemical polishing. In certain embodiments, the patterned lay-out comprises horizontal metal lines and the first vertical metal vias. In certain embodiments, the horizontal metal lines and the vertical metal vias have a width of at least 1 micrometer. In certain embodiments, the horizontal metal lines and the vertical metal vias have a diameter of at least 1 micrometer. In certain embodiments, the substrate is a metal substrate. In certain embodiments, the substrate is a copper substrate.

Another apect of the invention provides a method of making making high-density interconnects on a substrate using one or more single layer membranes, each having a distinct patterned lay-out, wherein the method is conducted without use of photolithography or chemical polishing. In certain embodiments, a plurality of single layer membranes are used and a multi-layer, multi-dimensional patterned lay-out is produced on the substrate.

### BRIEF DESCRIPTION OF THE DRAWINGS

FIG. 1 shows a traditional prior art RDL metal fabrication process, which includes steps such as dielectric layer deposition, dielectric layer etching, metal layer deposition, and chemical mechanical polishing (CMP). This process is repeated layer by layer to create multi-layer RDL metal interconnects.

FIG. 2 show a process for customized membrane template fabrication.

FIG. 3 shows a final etching pattern layouts for single layer patterned membranes, each having a different layout, with horizontal lines and vertical vias.

FIG. 4 shows electroplated results for horizontal metal lines and vertical metal vias.

FIG. 5 shows SEM images of top surface and cross-sectional views of membranes after bonding.

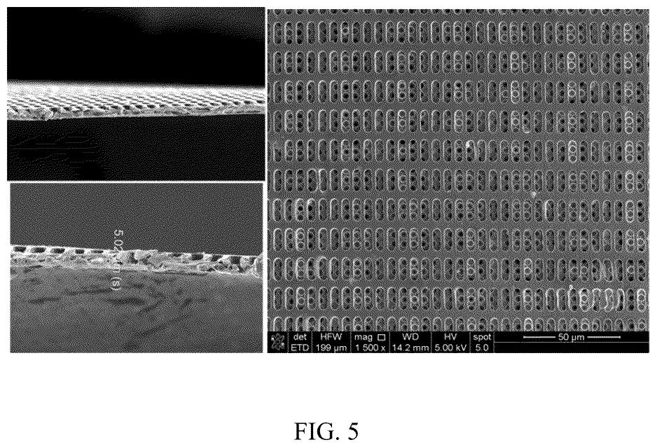

FIG. 6 shows the final electroplated two-layer copper metal structures.

FIG. 7 shows a flow chart of the prior art approach.

FIG. 8 shows a flow diagram of an embedment of the approach of the invention.

### DETAILED DESCRIPTION

The invention generally provides a cost-effective, low-cost multi-layer RDL fabrication method using customized advanced membrane technology. This customized membrane template can be patterned according to the metal interconnect layout and adapted for multi-layer configurations. This approach can achieve metal line sizes as small as 1 micrometer, potentially reducing energy consumption and water usage. The fabrication process time can be reduced by 80% compared to traditional methods. This rapid single-step fabrication method has great potential to simply the RDL fabrication process and reduce the cost in advanced manufacturing industry.

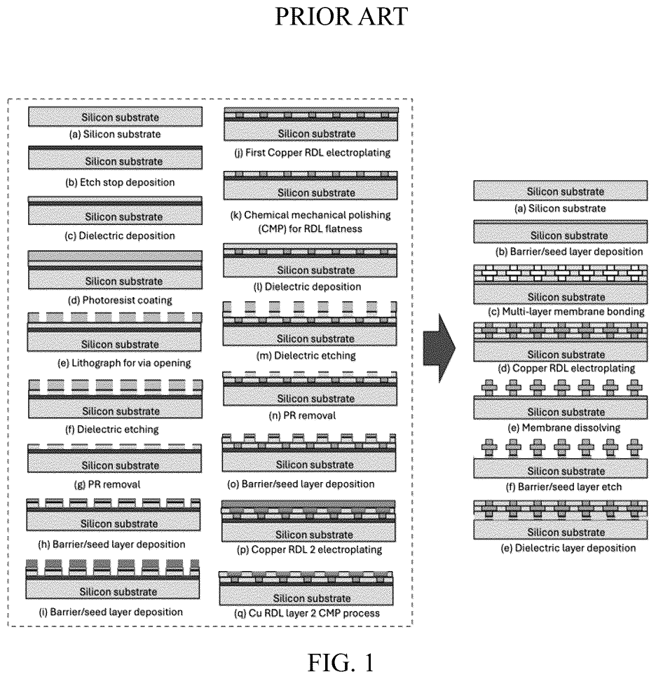

Traditional RDL metal fabrication, as depicted in FIG. 1, includes steps such as dielectric layer deposition, dielectric layer etching, metal layer deposition, and chemical mechanical polishing (CMP). This process is repeated layer by layer to create multi-layer RDL metal interconnects. For a six-layer RDL metal interconnect on a silicon or glass substrate, this sequence must be repeated six times to ensure robust metal connections for advanced substrate interconnects. The entire RDL fabrication process involves lithography, photoresist coating, chemical vapor deposition (CVD), physical vapor deposition (PVD), etching, and chemical mechanical polishing, which consumes significant amounts of chemicals, water, and other resources.

### Customized Membrane Template Fabrication

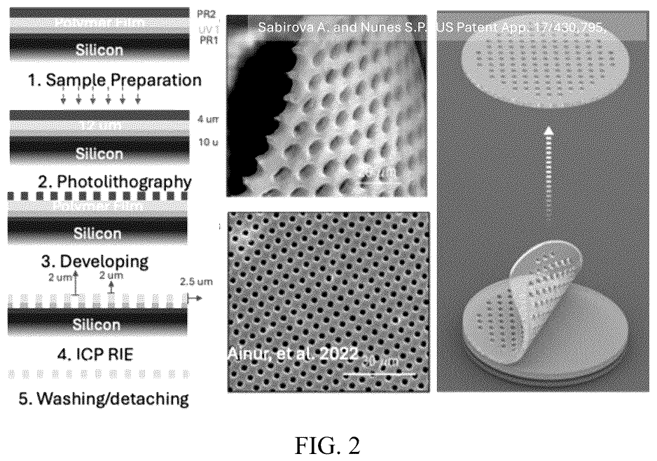

FIG. 2 describes a process for customized membrane template fabrication. The membrane layers can be fabricated using the membrane fabrication process disclosed in US 2022/0143560, the entire disclosure of is incorporated by reference herein in its entirety. More specifically, the membrane fabrication includes producing a plurality of membrane layers using a photolithography technique followed by an inductive-coupled plasma reactive ion etching (ICP-RIE) process. For example, the membrane layers can be formed by using lithography to deposit a polymer layer on a substrate, and then etching the pores into the polymer layer in the pattern of the desired pore structure. The membrane layers can be formed of a polymeric film, for example, poly(ethylene terephthalate) (PET).

### Single-Layer CU-RDL Fabrication

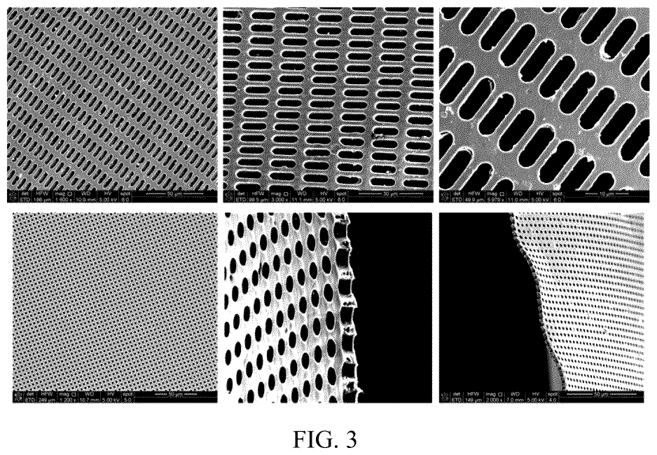

To achieve single layer patterned membrane, different layouts have been designed, with horizontal lines and vertical vias. The final etching pattern layouts are shown in FIG. 3. The via diameters are: circular: 2.5 um, rectangular: 12 um×4 um. The thickness of a single membrane is 2.5 um thickness. After the fabrication, the free-standalone membrane will be bonded to the copper seed layer for copper interconnect electreoplating.

Surface treatments are needed to bond the membrane to the seed layer for electroplating process and to bond membranes with each other without loosing their structures. For our developed process, we use first: oxygen plasma treatment, second: chemical treatment with polydopamine.

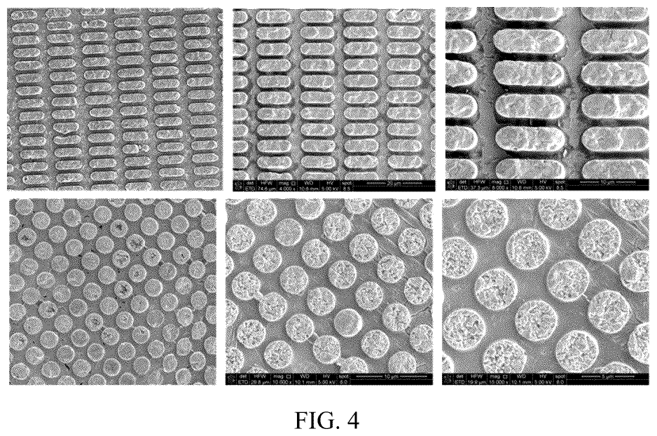

With good bonding quality between the membrane and seed layer, electroplating process will be conducted using current density 2 ASD, for 20 minutes. The electroplated results for horizontal metal lines and vertical metal vias are illustrated in FIG. 4. After the electroplating process, the membrane layer will be released using typical chemicals solutions.

### Multi-Layer CU-RDL Fabrication

In this process, multi-layer membrane stacking was developed. The stacking of the membrane requires typical bonding pressure and bonding temperature. The bonding process will be implemented on Fine-tech flip-chip bonder with precise pressure and temperature control. For two-layer membrane bonding, the optimal bonding temperature is 100° C., and bonding pressure is 20 kPa. For three-layer membrane bonding, the bonding time was increased while bonding temperature and pressure remained similar.

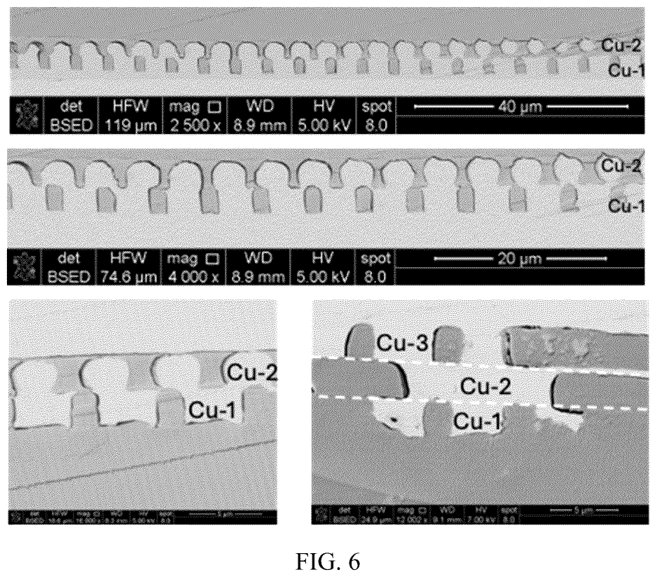

In FIG. 6, the final electroplated two-layer copper metal structures are shown. A seamless connection between the copper layer-1 and copper layer-2 can be observed. In addition, three layer copper metal structures are also shown in FIG. 6 (bottom right panel). Seamless bonding and connections between the metal are clearly presented. After the multi-layer copper metal structures fabrications, the sacrificial membrane layer is removed and coated the dielectric films on the glass or silicon substrate. The minimal line width shown in this fabrication is 1 um, with via diameter of 2 um. The pitch and via diameter can be pushed even further down to submicron size.

The data herein show development of an ultra-fast fabrication process for multi-layer RDL copper layers on the silicon or glass substrate for fine-pitch integrations. The demonstrated metal line width can be as small as 1 um, while the demonstrated via diameter can be reduced down to 1 um. This approach has great potential to reduce the fabrication cost and energy saving of the tradition RDL fabrications process.

### INCORPORATION BY REFERENCE

References and citations to other documents, such as patents, patent applications, patent publications, journals, books, papers, web contents, have been made throughout this disclosure, including to the Supplementary. The Supplementary, and all other such documents are hereby incorporated herein by reference in their entirety for all purposes.

### EQUIVALENTS

The invention may be embodied in other specific forms without departing from the spirit or essential characteristics thereof. The foregoing embodiments are therefore to be considered in all respects illustrative rather than limiting on the invention described herein.

### EXAMPLES

Provided herein is a revolutionary semiconductor manufacturing method capable of creating multi-layer, multi-dimensional, high-density metal interconnect substrates at high-speed using a single-step process. This customized advanced membrane technology allows for precise designs according to metal interconnect layouts and supports multi-layer configurations. This enables electrochemical deposition of complex metal layer structures in under 10 minutes, reducing fabrication time by 80% compared to traditional methods. This rapid, single-step process simplifies the redistribution layer (RDL) fabrication, lowers costs, and has great potential for applications in advanced packaging, chiplets, and high-end solar cells. Additionally, it could lead to reduced energy consumption and water usage, with a 95% decrease in CO₂ emissions. This innovation enables high-volume production of advanced packaging without the need for expensive methods like photolithography or chemical polishing, significantly reducing capital costs for the advanced packaging industry.

Advanced packaging and heterogeneous 3D integration are vital technologies for the next generation of high-performance computing systems. In 2023/2024, advanced packaging made up 7% of TSMC's revenue, approximately $5 billion USD. To achieve higher metal interconnection densities for chip stacking, the industry relies on expensive lithography processes and chemical mechanical polishing (CMP). CMP is essential for planarizing dielectrics and metal films in the fabrication of Redistribution Layers (RDL) for advanced packaging substrates. However, traditional RDL processes involve numerous steps for depositing metal and dielectric materials and require significant slurry and electricity for chemical polishing. This method is costly and resource-intensive, resulting in substantial environmental impacts. There is an urgent need to reduce slurry and electricity consumption without sacrificing CMP productivity for environmental sustainability. Our innovative “additive manufacturing metal method” aims to lower fabrication costs by up to 40% while achieving a 90-99% reduction in energy use and producing zero waste, leading to a 90% decrease in CO₂ emissions.

The methods herein are revolutionizing the semiconductor packaging industry with efficient single-step multi-layer metal interconnects. This invention can accelerate and enable the production of high-performance semiconductor chips. This method allows for metal line creation as small as 1 micrometer while significantly reducing energy consumption and water usage. Certain advantages include being 100 times faster than conventional methods, reducing manufacturing steps by up to 60%, and achieving full-size panel and wafer deposition. It delivers a resolution of 4 μm, with a target of 1 μm, and maintains 90% of the conductivity of bulk copper. Furthermore, it offers 98% less embodied energy compared to photolithography and achieves an 80% reduction in fabrication time, eliminating the costly photolithography step. Overall, this innovative process results in a 90-99% reduction in energy use and zero waste, leading to a remarkable 90% decrease in CO₂ emissions, making it a sustainable solution for advanced packaging.

### Example 1: Comparison of the 4-Layer Redistribution Layer (RDL): Prior Art Approach Vs. Approach of the Invention

| | | | Percentage |
|---|---|---|---|
| Aspect | Traditional approach | Our approach | Improvement |
| Total Time | 2-3 weeks | 7-12 days | 45.7% faster |
| Estimate | (approx.) | (approx.) | |
| Total Cost | $4,400-$9,600 | $1,890-$4,550 | 54% cheaper |
| Estimate | | | |
| Environmental | High: Multiple RDL | Moderate: Chemical | |
| Impact | layers, CMP steps, | waste, copper | |
| | via drilling, and | deposition, | |
| | planarization | photolithography. | |
| | generate significant | | |
| | waste. | | |
| Total CO₂ | 540-1,320 kg CO₂ | 311-800 kg CO₂ | 40.3% fewer |
| Emissions | (estimated across | (estimated across | emissions |
| | all steps) | all steps) | |
| Total Energy | 1,500-3,750 kWh | 550-1,500 kWh | 60.8% less |
| Consumption | | | energy |
| Total Waste | Slurry, wastewater, | Chemical waste | 50-70% less |
| Generation | abrasives, etching | (developer, etchant), | waste |
| | chemicals, drilling | water waste, | |
| | waste. | electroplating waste. | |

### Example 2: Comparison of the 8-Layer RDL: Prior Art Approach Vs. Approach of the Invention

| | | | Percentage |
|---|---|---|---|
| Aspect | Traditional approach | Our approach | Improvement |
| Total Time | 4-6 weeks | 1-1.5 weeks | 72.9% faster |
| Estimate | (approx.) | (approx.) | |
| Total Cost | $8,800-$19,200 | $1,890-$4,550 | 77.0% |
| Estimate | | | cheaper |
| Environmental | High: Multiple RDL | Moderate: Chemical | |
| Impact | layers, CMP steps, | waste, copper | |
| | via drilling, and | deposition, | |
| | planarization | photolithography. | |
| | generate significant | | |
| | waste. | | |
| Total CO₂ | 1,080-2,640 kg CO₂ | 311-800 kg CO₂ | 70.2% fewer |
| Emissions | (estimated across all | (estimated across all | emissions |
| | steps) | steps) | |
| Total Energy | 3,000-7,500 kWh | 550-1,500 kWh | 80.5% less |
| Consumaption | | | energy |
| Total Waste | Slurry, wastewater, | Chemical waste | 40-50% less |
| Generation | abrasives, etching | (developer, etchant), | waste |
| | chemicals, drilling | water waste, | |
| | waste. | electroplating waste. | |

### Example 3: Comparing Prior Art Approach to Approach of the Invention for Multi-Layer Creation

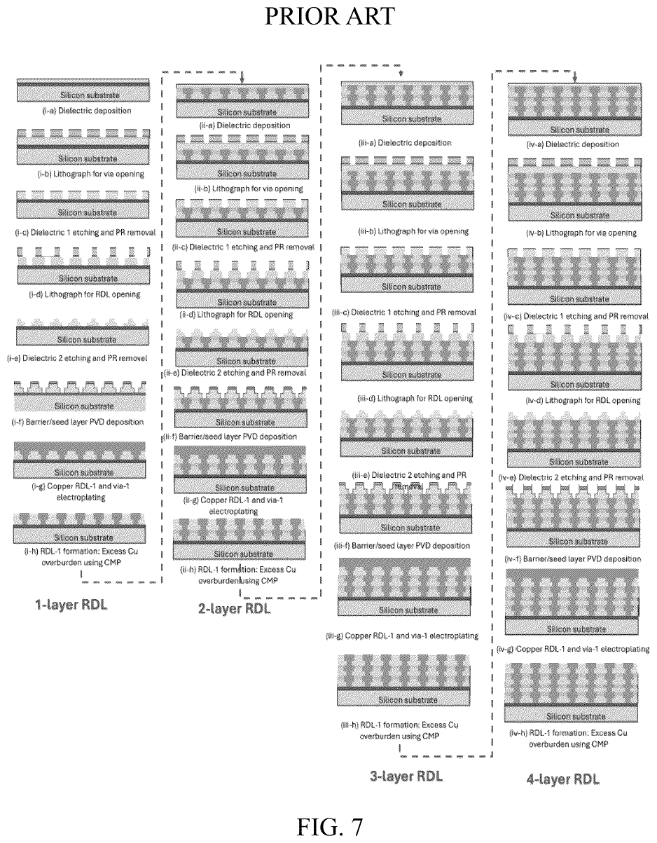

FIG. 7 shows a flow chart of the prior art approach.

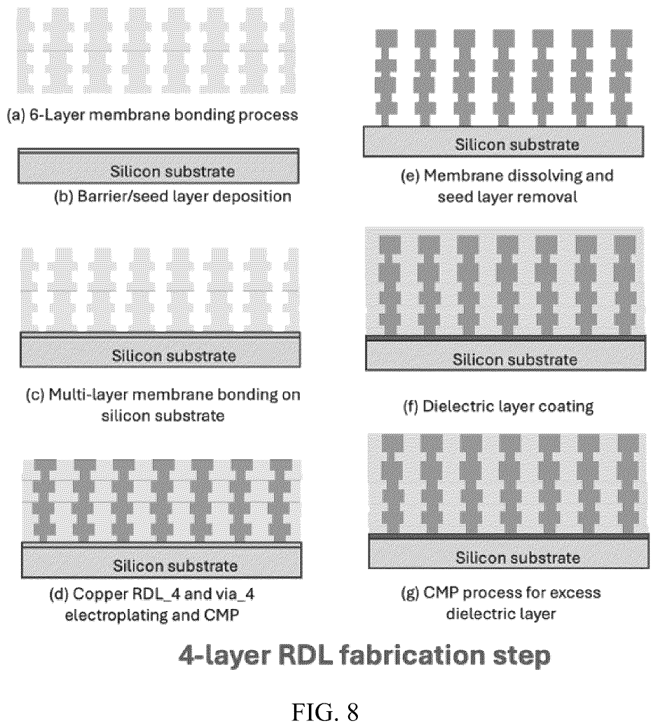

FIG. 8 shows a flow diagram of an embedment of the approach of the invention.

| | | | Cost | | CO₂ | |
|---|---|---|---|---|---|---|
| | Time | | Estimate | | Emissions | |
| Step | Estimate | | per Step | Environmental Impact | (kg CO₂) | |
| 1. Substrate | 1-2 | weeks | $500-$1,500 | Moderate Impact: Energy-intensive | 50-150 | kg CO₂ |
| Preparation & Base | | | | Potential CO₂ from manufacturing | | |
| Layer Formation | | | | equipment (e.g., CO₂, VOCs). Uses | | |
| | | | | hazardous chemicals in substrate etching. | | |
| 2. RDL Layer 1 | 2-4 | days | $800-$1,000 | Moderate Impact: Copper deposition and | 40-100 | kg CO₂ |
| (Copper Deposition, | | | | photolithography consume chemicals | | |
| Photolithography) | | | | (developer, etchants), water, and energy. | | |
| | | | | Wastewater from photoresist etching | | |
| 3. CMP After RDL | 1-2 | days | $200-$400 | High Impact: Uses water, abrasives, and | 30-70 | kg CO₂ |
| Layer 1 | | | | chemicals. Waste slurry needs treatment. | | |
| 4. RDL Layer 2 | 2-4 | days | $500-$1,000 | Moderate Impact: Similar to Step 2: uses | 40-100 | kg CO₂ |
| (Copper Deposition, | | | | photolithography chemicals and water for | | |
| Photolithography) | | | | rinsing. | | |
| 5. CMP After RDL | 1-2 | days | $200-$400 | High Impact: Similar to Step 3, with | 10-70 | kg CO₂ |
| Layer 2 | | | | additional water and chemical | | |
| | | | | consumption. | | |
| 6. RDL Layer 3 | 2-4 | days | $500-$1,000 | Moderate Impact: Photolithography | 40-100 | kg CO₂ |
| (Copper Deposition, | | | | chemicals and copper deposition chemicals | | |
| Photolithography) | | | | used again, along with energy consumption | | |
| | | | | for UV exposure. | | |
| 7. CMP After RDL | 1-2 | days | $200-$400 | High Impact: Similar to previous CMP steps. | 30-70 | kg CO₂ |
| Layer 3 | | | | Involves slurry waste and energy use. | | |
| 8. RDL Layer 4 | 2-4 | days | $500-$1,000 | Moderate Impact: Involves the same | 40-100 | kg CO₂ |
| (Copper Deposition, | | | | materials and processes as previous RDL | | |
| Photolithography) | | | | layers. | | |
| 9. CMP After RDL | 1-2 | days | $200-$400 | High Impact: Similar to earlier CMP steps: | 30-70 | kg CO₂ |
| Layer 4 | | | | slurry and wastewater are the main | | |
| | | | | environmental concerns. | | |
| 10. Via Formation & | 2-4 | days | $300-$800 | Moderate to high: Impact: Drilling requires | 100-200 | kg CO₂ |
| Drilling (Microvias or | | | | energy and generates hazardous waste, | | |
| Through-Vias) | | | | such as dust, abrasive materials, and | | |
| | | | | coolants. Significant emissions from | | |
| | | | | machinery. | | |
| 11. Via CMP (Post- | 1-2 | days | $200-$400 | High Impact: Similar to CMP after RDL | 30-70 | kg CO₂ |
| Drilling Planarization) | | | | layers, but involves additional chemicals | | |
| | | | | and water for the via structure. | | |
| 12. Final Planarization | 1-2 | days | $200-$400 | Moderate Impact: Similar to CMP steps. | 30-70 | kg CO₂ |
| (if necessary) | | | | Energy and water consumption, with | | |
| | | | | chemical waste. | | |

| | Energy | | | |
|---|---|---|---|---|
| | Consumption | | Waste | |
| Step | (kWh) | | Generation | Description |
| 1. Substrate | 200-600 | kWh | Chemical waste | Preparing the base substrate, |
| Preparation Base | | | (etchants), | cleaning, and depositing the first |
| Layer Formation | | | wastewater, | copper layer. |
| | | | energy-intensive | |
| | | | equipment | |
| 2. RDL Layer 1 | 150-400 | kWh | Chemical waste | Depositing the first RDL layer |
| (Copper Deposition, | | | (developer, | (copper) via electroplating or |
| Photolithography) | | | etchant, water | sputtering. |
| | | | waste | |
| 3. CMP After RDL | 100-250 | kWh | Slurry waste | Chemical Mechanical |
| Layer 1 | | | wastewater, | Planarization (CMP) to smooth |
| | | | abrasives | the first RDL layer surface. |
| 4. RDL Layer 2 | 150-400 | kWh | Chemical waste | Depositing the second RDL layer |
| (Copper Deposition, | | | (developer, | and photolithography to pattern |
| Photolithography) | | | etchant), | traces. |
| | | | wastewater | |
| 5. CMP After RDL | 100-250 | kWh | Slurry waste | CMP to smooth the second RDL. |
| Layer 2 | | | wastewater, | layer for the next process step. |
| | | | abrasives | |
| 6. RDL Layer 3 | 150-400 | kWh | Chemical waste | Depositing the third RDL layer |
| (Copper Deposition, | | | (developer, | and patterning it with |
| Photolithography) | | | etchant), | photolithography. |
| | | | wastewater | |
| 7. CMP After RDL | 100-250 | kWh | Slurry waste | CMP after third RDL layer to |
| Layer 3 | | | wastewater, | ensure flatness and readiness for |
| | | | abrasives | further steps. |
| 8. RDL Layer 4 | 150-400 | kWh | Chemical waste | Depositing the fourth RDL |
| (Copper Deposition, | | | (developer, | layer and photolithography for |
| Photolithography) | | | etchant), | patterning. |
| | | | wastewater | |
| 9. CMP After RDL | 100-250 | kWh | Slurry waste | CMP after the final RDL layer to |
| Layer 4 | | | wastewater, | prepare for via formation or final |
| | | | abrasives | tests. |
| 10. Via Formation & | 250-500 | kWh | Drilling waste, | Drilling of microvias or through- |
| Drilling (Microvias or | | | abrasives, and | vias, via electroplating for via |
| Through-Vias) | | | coolants | metallization. |
| 11. Via CMP (Post- | 100-250 | kWh | Wastewater, | CMP to smooth the via structure |
| Drilling Planarization) | | | slurry, abrasives | for the next layer. |
| 12. Final Planarization | 100-250 | kWh | Slurry waste | Final CMP step to smooth the |
| (if necessary) | | | wastewater, | entire surface before solder |
| | | | abrasives | mask application. |

### Estimated Total Environmental Impact (Excluding Final Testing & Packaging)

| Total CO₂ | Total Energy | Total Waste |
|---|---|---|
| Emissions | Consumption | Generation |
| Approx. 600-1,450 | Approx. 1,750-4,500 | Chemical waste, |
| kg CO₂ | kWh | wastewater, slurry, |
| | | abrasives, drilling waste |

### Explanation of Environmental Impact Numbers:

1. CO₂ Emissions (kg CO₂):
   These numbers are rough estimates based on energy consumption, fuel usage in manufacturing equipment, and the CO₂ intensity of electricity used in different regions. Steps involving energy-intensive machinery (such as copper deposition, CMP, and via drilling) result in higher CO₂ emissions.
   Drilling and plating (Step 10) have the highest COD emissions due to the energy consumption of the drilling equipment and waste management processes.
2. Energy Consumption (kWh):
   This refers to the electricity used by equipment for each step of the process, including photolithography, copper deposition, CMP, and via drilling.
   The higher energy-consuming steps include copper deposition, CMP, and via formation, as they involve machinery such as UV exposure systems, electroplating baths, and CMP polishing tools.
3. Waste Generation:
   Includes chemical waste, wastewater, and slurry from CMP processes. The drilling step generates waste such as metal shavings, abrasive materials, and coolants.
   Special attention is required for wastewater and slurry disposal, as they may contain hazardous chemicals, such as etchants, resist solvents, and abrasive particles. Waste management systems need to recycle or neutralize these substances before disposal.
4. High Impact Steps:
   Via Formation & Drilling (Step 10): The most energy-intensive and environmentally impactful process due to energy usage, dust generation, and hazardous waste from abrasives and coolants.
   CMP (Steps 3, 5, 7, 9, 11, 12): CMP involves abrasive slurries, chemicals, and large amounts of water, contributing to high waste volumes. Proper recycling of water and chemicals is crucial.
      An Embodiment of the Approach of the Invention—the Process Flow for 4-Layer RDL Fabrication with CMP (Environmental Impact Estimates)

| | | | Cost | | CO₂ | |
|---|---|---|---|---|---|---|
| | Time | | Estimate | | Emissions | |
| Step | Estimate | | per Step | Environmental Impact | (kg CO₂) | |
| 1. Membrane | 2-4 | days | $500-$1,000 | Moderate Impact: Copper deposition and | 40-100 | kg CO₂ |
| lithography process | | | | photolithography consume chemicals | | |
| | | | | (developer, etchants), water, and energy. | | |
| | | | | Wastewater from photoresist etching | | |
| 2. Membrane | 1-2 | days | $800-$1,000 | Low Impact: The bonding protection gas | 40-100 | kg CO₂ |
| bonding process | | | | and electricity usage. | | |
| 2. 4-layer RDL | 1 | day | $50-$500 | Moderate Impact: Copper deposition | 1-30 | kg CO₂ |
| copper | | | | consume chemicals (developer, etchants), | | |
| electrochemical | | | | water, and energy. | | |
| depositions | | | | | | |
| 3. Membrane | 1 | day | $50-$500 | Moderate Impact: chemical etching wase, | 100-200 | kg CO₂ |
| dissolving and seed | | | | and seed layer etching chemicals | | |
| layer removal | | | | | | |
| Dielectric layer | 1 | day | $200-$400 | No Impact: dielectric coating process | 10-30 | kg CO₂ |
| coating on the | | | | | | |
| multi-layer copper | | | | | | |
| 4. CMP After all-in- | 1-2 | days | $200-$400 | High Impact: Similar to previous CMP steps. | 30-70 | kg CO₂ |
| one 4-layer RDL | | | | Involves slurry waste and energy use. | | |
| formation | | | | | | |

| | Energy | | | |
|---|---|---|---|---|
| | Consumption | | Waste | |
| Step | (kWh) | | Generation | Description |
| 1. Membrane | 150-400 | kWh | Chemical waste | Depositing the first |
| lithography process | | | (developer, | RDL layer (copper) via |
| | | | etchant), water | electroplating or |
| | | | waste | sputtering. |
| 2. Membrane | 50-100 | kWh | Formic acid gas | Bonding the 4-layer |
| bonding process | | | protection | patented membrane |
| | | | during the | together with |
| | | | bonding | temperature and force |
| | | | process. | control. |
| 2. 4-layer RDL | 50-100 | kWh | Chemical waste | Depositing the 4-layer |
| copper | | | of the | depositions. |
| electrochemical | | | electrochemical | |
| depositions | | | plating solutions | |
| 3. Membrane | 100-250 | kWh | Chemical waste | |
| dissolving and seed | | | of the etching | |
| layer removal | | | process | |
| Dielectric layer | 100-250 | kWh | | |
| coating on the | | | | |
| multi-layer copper | | | | |
| 4. CMP After all-in- | 100-250 | kWh | Slurry waste, | CMP after third RDL |
| one 4-layer RDL | | | wastewater, | layer to ensure flatness |
| formation | | | abrasives | and readiness for |
| | | | | further steps. |

What is claimed is:

1. A method for making high-density interconnects on a substrate, the method comprising:
coupling a first single layer membrane to a substrate, wherein the first single layer membrane has a first patterned lay-out that comprises first horizontal lines and first vertical vias;
conducting an electroplating process to produce first horizontal metal lines and first vertical metal vias on the substrate; and
releasing the first single layer membrane from the substrate that now comprises a first pattern of the first horizontal metal lines and the first vertical metal vias.

2. The method of claim 1, wherein the method is conducted without photolithography or chemical polishing.

3. The method of claim 1, wherein the first horizontal metal lines and the first vertical metal vias have a width of at least 1 micrometer.

4. The method of claim 1, wherein the first horizontal metal lines and the first vertical metal vias have a diameter of at least 1 micrometer.

5. The method of claim 1, wherein the first single layer substrate comprises a polymer and the substrate is a metal substrate.

6. The method of claim 5, wherein the substrate is a copper substrate.

7. The method of claim 1, wherein the method is conducted with the first single layer membrane and a second single member membrane.

8. The method of claim 7, wherein the second single member membrane has a second patterned lay-out that comprises second horizontal lines and second vertical vias and the second patterned lay-out is different from the first patterned lay-out.

9. The method of claim 8, wherein the electroplating process produces the first patterned lay-out and the second patterned layout on the substrate, thereby producing a multi-layer, multi-dimensional patterned lay-out on the substrate.

10. The method of claim 9, wherein the electroplating process produces the first patterned lay-out and the second patterned layout on the substrate at the same time.

11. A method of making a single layer membrane having a patterned lay-out, the method comprising:
providing a polymer membrane;
attaching the polymer membrane to a tape film;
coupling a patterned photomask to the polymer membrane, the patterned photomask comprising a pattern of distributed cylindrical isopores;
exposing the polymer membrane and patterned photomask to light to thereby etch the pattern from the photomask onto the polymer membrane; and
removing the tape film, thereby producing a single layer membrane having a patterned lay-out.

12. The method of claim 11, wherein single layer membrane having the patterned lay-out is used in a process to produce a substrate having the patterned lay-out.

13. The method of claim 12, wherein the method is conducted without photolithography or chemical polishing.

14. The method of claim 12, wherein the patterned lay-out comprises horizontal metal lines and the first vertical metal vias.

15. The method of claim 14, wherein the horizontal metal lines and the vertical metal vias have a width of at least 1 micrometer.

16. The method of claim 14, wherein the horizontal metal lines and the vertical metal vias have a diameter of at least 1 micrometer.

17. The method of claim 12, wherein the substrate is a metal substrate.

18. The method of claim 17, wherein the substrate is a copper substrate.

19. A method of making making high-density interconnects on a substrate using one or more single layer membranes, each having a distinct patterned lay-out, wherein the method is conducted without use of photolithography or chemical polishing.

20. The method of claim 19, wherein a plurality of single layer membranes are used and a multi-layer, multi-dimensional patterned lay-out is produced on the substrate.
